(19) United States
(12) Patent Application Publication
(10) Pub. No.: US 2023/0007763 A1
(43) Pub. Date: Jan. 5, 2023

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventor: Koutaro MIYASHITA, Oyama-shi (JP)

(73) Assignee: Gigaphoton Inc., Tochigi (JP)

(21) Appl. No.: 17/835,312

(22) Filed: Jun. 8, 2022

(30) Foreign Application Priority Data
Jul. 5, 2021 (JP) 2021-111238

(51) Int. Cl. H05G 2/00; G03F 7/20

(52) U.S. Cl. CPC H05G 2/006; G03F 7/70033

(57) ABSTRACT

An extreme ultraviolet light generation apparatus includes a chamber in which a target is turned into plasma to generate extreme ultraviolet light, a target generator, an illumination device, and an imaging device receiving illumination light and capturing a target image. The imaging device includes a first transfer optical system transferring the target image, a mask having an opening formed at a transfer position of the first transfer optical system, a second transfer optical system transferring the target image at the opening, an image intensifier arranged such that a photoelectric surface is located at a transfer position of the second transfer optical system, a third transfer optical system transferring the target image at a fluorescent surface, an image sensor arranged at a transfer position of the third transfer optical system, and a moving mechanism capable of moving the mask by an amount equal to or larger than the opening.

### CROSS-REFERENCE TO RELATED APPLICATIONS

The present application claims the benefit of Japanese Patent Application No. 2021-111238, filed on Jul. 5, 2021, the entire contents of which are hereby incorporated by reference.

### BACKGROUND

### 1. Technical Field

The present disclosure relates to an extreme ultraviolet light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, the development of an exposure apparatus that combines an extreme ultraviolet (EUV) light generation apparatus that generates EUV light having a wavelength of about 13 nm and reduced projection reflection optics is expected. As the EUV light generation apparatus, a laser produced plasma (LPP) type apparatus using plasma generated by irradiating a target substance with laser light has been developed.

### LIST OF DOCUMENTS

### Patent Documents

Patent Document 1: Japanese Unexamined Patent Application No. 2016-145793
Patent Document 2: Japanese Unexamined Patent Application No. 2005-166722

### SUMMARY

An extreme ultraviolet light generation apparatus according to an aspect of the present disclosure includes a chamber in which a target supplied to a plasma generation region at inside thereof is turned into plasma and extreme ultraviolet light is generated, a target generator configured to supply the target to the plasma generation region in the chamber, an illumination device connected to the chamber and configured to output illumination light toward the target supplied from the target generator, and an imaging device connected to the chamber and configured to receive the illumination light and capture an image of the target. Here, the imaging device includes a first transfer optical system configured to transfer the image of the target, a mask having an opening formed at a transfer position of the first transfer optical system, a second transfer optical system configured to transfer the image of the target at the opening, an image intensifier having a photoelectric surface and a fluorescent surface and arranged such that the photoelectric surface is located at a transfer position of the second transfer optical system, a third transfer optical system configured to transfer the image of the target at the fluorescent surface, an image sensor arranged at a transfer position of the third transfer optical system and configured to capture the image of the target transferred by the third transfer optical system, and a moving mechanism capable of moving the mask by an amount equal to or larger than the opening.

An imaging device according to another aspect of the present disclosure is an imaging device configured to capture an image of a target supplied from a target generator while receiving illumination light radiated to the target. The imaging device includes a first transfer optical system configured to transfer the image of the target, a mask having an opening formed at a transfer position of the first transfer optical system, a second transfer optical system configured to transfer the image of the target at the opening, an image intensifier having a photoelectric surface and a fluorescent surface and arranged such that the photoelectric surface is located at a transfer position of the second transfer optical system, a third transfer optical system configured to transfer the image of the target at the fluorescent surface, an image sensor arranged at a transfer position of the third transfer optical system and configured to capture the image of the target transferred by the third transfer optical system, and a moving mechanism capable of moving the mask by an amount equal to or larger than the opening.

An electronic device manufacturing method according to another aspect of the present disclosure includes generating extreme ultraviolet light using an extreme ultraviolet light generation apparatus, emitting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a chamber in which a target supplied to a plasma generation region at inside thereof is turned into plasma and the extreme ultraviolet light is generated, a target generator configured to supply the target to the plasma generation region in the chamber, an illumination device connected to the chamber and configured to output illumination light toward the target supplied from the target generator, and an imaging device connected to the chamber and configured to receive the illumination light and capture an image of the target. The imaging device includes a first transfer optical system configured to transfer the image of the target, a mask having an opening formed at a transfer position of the first transfer optical system, a second transfer optical system configured to transfer the image of the target at the opening, an image intensifier having a photoelectric surface and a fluorescent surface and arranged such that the photoelectric surface is located at a transfer position of the second transfer optical system, a third transfer optical system configured to transfer the image of the target at the fluorescent surface, an image sensor arranged at a transfer position of the third transfer optical system and configured to capture the image of the target transferred by the third transfer optical system, and a moving mechanism capable of moving the mask by an amount equal to or larger than the opening.

An electronic device manufacturing method according to another aspect of the present disclosure includes inspecting a defect of a reticle by irradiating the reticle with extreme ultraviolet light generated by an extreme ultraviolet light generation apparatus, selecting a reticle using a result of the inspection, and exposing and transferring a pattern formed on the selected reticle onto a photosensitive substrate. Here, the extreme ultraviolet light generation apparatus includes a chamber in which a target supplied to a plasma generation region at inside thereof is turned into plasma and the extreme ultraviolet light is generated, a target generator configured to supply the target to the plasma generation region in the chamber, an illumination device connected to the chamber and configured to output illumination light toward the target supplied from the target generator, and an imaging device connected to the chamber and configured to receive the illumination light and capture an image of the target. The imaging device includes a first transfer optical system configured to transfer the image of the target, a mask having an opening formed at a transfer position of the first transfer optical system, a second transfer optical system configured to transfer the image of the target at the opening, an image intensifier having a photoelectric surface and a fluorescent surface and arranged such that the photoelectric surface is located at a transfer position of the second transfer optical system, a third transfer optical system configured to transfer the image of the target at the fluorescent surface, an image sensor arranged at a transfer position of the third transfer optical system and configured to capture the image of the target transferred by the third transfer optical system, and a moving mechanism capable of moving the mask by an amount equal to or larger than the opening.

### BRIEF DESCRIPTION OF THE DRAWINGS

Embodiments of the present disclosure will be described below merely as examples with reference to the accompanying drawings.

FIG. 1 schematically shows the configuration example of an EUV light generation apparatus according to a comparative example.

FIG. 2 is an enlarged view schematically showing the configuration of an imaging device.

FIG. 3 shows a typical example of an image of a target obtained by the imaging device.

FIG. 4 schematically shows the configuration of an imaging device applied to the EUV light generation apparatus according to a first embodiment.

FIG. 5 is an example of a mask used in the imaging device.

FIG. 6 is an explanatory diagram of the definition of each parameter related to the mask.

FIG. 7 is a flowchart showing an example of a mask movement control method in the EUV light generation apparatus according to the first embodiment.

FIG. 8 is a graph schematically showing an example of the operation of the imaging device based on the control of the flowchart of FIG. 7.

FIG. 9 shows a modification of the mask.

FIG. 10 is an explanatory diagram of the definition of each parameter related to the mask shown in FIG. 9.

FIG. 11 schematically shows the configuration of the imaging device applied to the EUV light generation apparatus according to a second embodiment.

FIG. 12 shows the configuration of the mask applied to the second embodiment.

FIG. 13 is an explanatory diagram of the definition of each parameter related to the mask shown in FIG. 12.

FIG. 14 is a flowchart showing an example of a mask movement control method in the EUV light generation apparatus according to the second embodiment.

FIG. 15 shows a modification of the mask.

FIG. 16 shows a state after the mask shown in FIG. 15 is rotated by 90°.

FIG. 17 is an explanatory diagram of the definition of each parameter related to the mask shown in FIG. 15.

FIG. 18 is an explanatory diagram of the definition of each parameter related to the mask shown in FIG. 15.

FIG. 19 schematically shows the configuration of an exposure apparatus connected to the EUV light generation apparatus.

FIG. 20 schematically shows the configuration of an inspection device connected to the EUV light generation apparatus.

### DESCRIPTION OF EMBODIMENTS

### <Contents>

1. Description of terms
2. Overview of EUV light generation apparatus according to comparative example

2.1 Configuration

2.2 Operation

2.3 Problem

### 3. First Embodiment

3.1 Configuration

3.2 Operation

3.3 Mask movement control method

3.4 Effects

3.5 Modification of target measurement device

3.6 Modification of mask driving unit

3.7 Modification of mask
3.7.1 Configuration
3.7.2 Operation
3.7.3 Effects

### 4. Second Embodiment

4.1 Configuration

4.2 Operation

4.3 Mask movement control method

4.4 Effects

4.5 Modification of target measurement device

4.6 Modification of mask
4.6.1 Configuration
4.6.2 Operation
4.6.3 Effects
   5. Regarding mask replacement
   6. Electronic device manufacturing method

### 7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Description of Terms

A “target” is an object to be irradiated with laser light introduced into a chamber. The target irradiated with the laser light is turned into plasma and emits light including EUV light.

A “droplet” is a form of a target supplied into the chamber. The droplet may refer to a droplet-shaped target having a substantially spherical shape due to surface tension of a molten target substance.

A “plasma generation region” is a predetermined region in the chamber. The plasma generation region is a region in which a target output into the chamber is irradiated with laser light and in which the target is turned into plasma.

A “target trajectory” is a path along which a target output into the chamber travels. The target trajectory includes a travel axis of the target. The target trajectory intersects, in the plasma generation region, with an optical path of the laser light introduced into the chamber.

An “optical path axis” is an axis passing through the center of a beam cross section of the laser light along a travel direction of the laser light.

An “optical path” is a path through which the laser light passes. The optical path includes an optical path axis.

A “Z-axis direction” is a travel direction of the laser light when the laser light introduced into the chamber travels toward the plasma generation region. The Z-axis direction may be substantially the same as a direction in which the EUV light generation apparatus outputs EUV light.

A “Y-axis direction” is a direction in which a target generation unit outputs the target into the chamber, that is, a travel direction of the target. An “X-axis direction” is a direction perpendicular to the Y-axis direction and the Z-axis direction.

The expression “EUV light” is an abbreviation for “extreme ultraviolet light.” The “extreme ultraviolet light generation apparatus” is referred to as an “EUV light generation apparatus.”

The term “parallel” in the present specification may include a concept of substantially parallel which can be regarded as a range equivalent to substantially parallel in technical meaning. In addition, the term “perpendicular” or “orthogonal” in the present specification may include a concept of substantially perpendicular or substantially orthogonal which can be regarded as a range equivalent to substantially perpendicular or substantially orthogonal in technical meaning.

### 2. Overview of EUV Light Generation Apparatus According to Comparative Example

### 2.1 Configuration

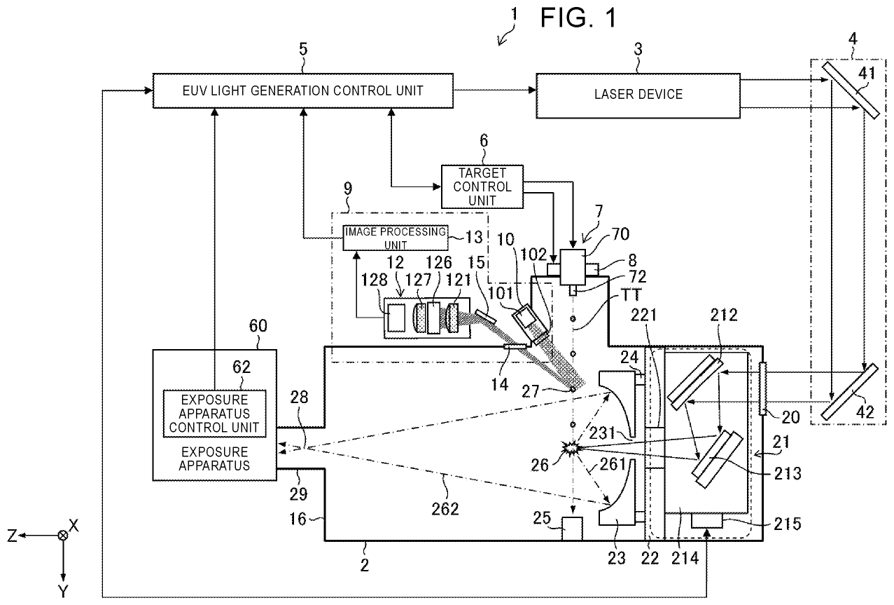

FIG. 1 schematically shows the configuration example of an EUV light generation apparatus 1 according to a comparative example. The comparative example of the present disclosure is an example recognized by the applicant as known only by the applicant, and is not a publicly known example admitted by the applicant.

The EUV light generation apparatus 1 is an LPP type EUV light generation apparatus. The EUV light generation apparatus 1 includes a chamber 2, a laser device 3, a beam delivery system 4, an EUV light generation control unit 5, and a target control unit 6.

The chamber 2 includes a target generator 7, a two-axis stage 8, a target measurement device 9, a window 20, a laser light concentrating optical system 21, a plate 22, an EUV light concentrating mirror 23, an EUV light concentrating mirror holder 24, and a target receiver 25. The chamber 2 is a sealable container. The window 20 is arranged on the wall of the chamber 2, and the pulse laser light output from the laser device 3 is transmitted through the window 20.

The target generator 7 includes a tank 70 for storing target substance and a nozzle 72 including a nozzle hole for outputting the target substance in the Y-axis direction. The target substance is, for example, a material including tin, terbium, gadolinium, or a combination of any two or more thereof. Preferably, the target substance is tin. A target 27 supplied from the target generator 7 to a plasma generation region 26 in the chamber 2 may be a droplet or a jet.

A heater (not shown) is arranged on the outer wall of the tank 70, and the target substance in the tank 70 is heated by the heater to be melted. The pressure in the tank 70 is adjusted by a pressure adjuster (not shown). The nozzle 72 communicates with the tank 70, and the molten target substance is output from a nozzle hole of the nozzle 72. For generating a droplet, a piezoelectric element (not shown) is arranged at the nozzle 72.

The target generator 7 is arranged on the chamber 2 via the two-axis stage 8 which moves in the X-axis direction and the Z-axis direction. The two-axis stage 8 is a mechanism for adjusting the position of the target generator 7 so that the target 27 output from the target generator 7 is supplied to the plasma generation region 26. The driving of the two-axis stage 8 is controlled by the target control unit 6.

The target measurement device 9 includes an illumination device 10 and at least two imaging devices 12. In FIG. 1, only one imaging device 12 is illustrated for convenience of illustration. The imaging direction of the two imaging devices 12 is, for example, a direction perpendicular to the X axis and the direction perpendicular to the Z axis, respectively.

The illumination device 10 includes a light source 101 and a window 102. The light source 101 may be, for example, a lamp or an LED. One illumination device 10 may be provided, or a plurality of illumination devices 10 may be provided corresponding to each of the plurality of imaging devices 12.

In FIG. 1, the configuration in which reflection light from the target 27 is incident on the imaging device 12 is adopted, but the target measurement device 9 is not limited to such a reflection light type configuration, and may adopt a backlight type configuration.

The imaging device 12 includes a transfer optical system 121, an image intensifier 126, a transfer optical system 127, and an image sensor 128. The image sensor 128 may be, for example, a two-dimensional charge-coupled device (CCD) camera or a complementary metal-oxide semiconductor (CMOS) camera. The target measurement device 9 includes an image processing unit 13 which processes a signal (image data) obtained by the image sensor 128.

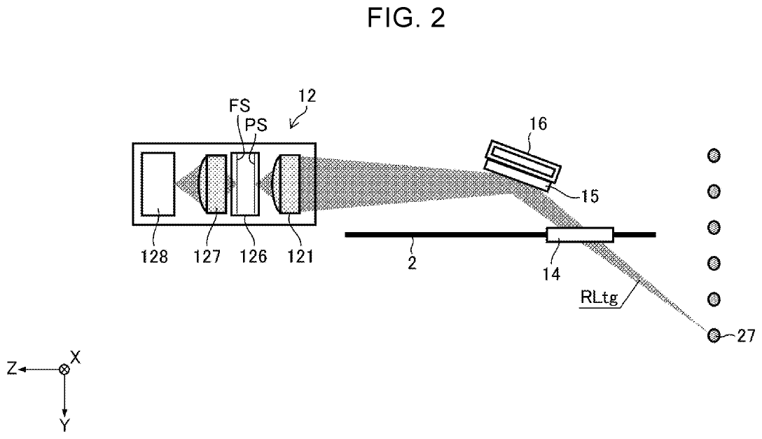

FIG. 2 is an enlarged view schematically showing the configuration of the imaging device 12. As shown in FIG. 2, the image intensifier 126 includes a photoelectric surface PS on the incident side and a fluorescent surface FS on the exit side.

The transfer optical system 121 is arranged such that reflection light RLtg from the target 27 illuminated by the illumination device 10 is transferred and imaged onto the photoelectric surface PS of the image intensifier 126. The reflection light RLtg is referred to as “target reflection light RLtg” in some cases. A part of the illumination light output from the illumination device 10 becomes the target reflection light RLtg.

The transfer optical system 127 and the image sensor 128 are arranged such that an image of the fluorescent surface FS of the image intensifier 126 is transferred and imaged onto the image sensor 128.

A window 14 through which the target reflection light RLtg is transmitted is arranged on the wall of the chamber. The target measurement device 9 includes a high reflection mirror 15 and a two-axis stage 16 for guiding the optical path of the target reflection light RLtg transmitted through the window 14 to the imaging device 12. The high reflection mirror 15 is arranged so as to reflect the target reflection light RLtg transmitted through the window 14 and to cause the the target reflection light RLtg to be incident on the imaging device 12. The high reflection mirror 15 is arranged on the two-axis stage 16. The two-axis stage 16 is a stage that includes an actuator movable in each direction of two axes perpendicular to each other. The driving of the two-axis stage 16 is controlled by the target control unit 6.

The laser device 3 outputs pulse laser light to be radiated to the target 27 supplied to the plasma generation region 26 in the chamber 2. Here, one target 27 may be irradiated with a plurality of pulses of the pulse laser light. For example, one target 27 is irradiated with first prepulse laser light, second prepulse laser light, and main pulse laser light in this order. In this case, the laser device 3 may be configured to include a first prepulse laser device which outputs the first prepulse laser light, a second prepulse laser device which outputs the second prepulse laser light, and a main pulse laser device which outputs the main pulse laser light.

Each of the first prepulse laser device and the second prepulse laser device may be a solid-state laser device such as a YAG laser device. The configuration in which the second prepulse laser device is omitted is also possible. The main pulse laser device 30 may be a gas laser device such as a CO₂ laser device.

The beam delivery system 4 is a beam transmission optical system for guiding the pulse laser light output from the laser device to the window 20 of the chamber 2 and introducing the pulse laser light into the chamber 2 through the window 20. The beam delivery system 4 is arranged outside the chamber 2.

The beam delivery system 4 includes high reflection mirrors 41, 42 for defining a transmission state of the laser light and an actuator (not shown) for adjusting the position, posture, and the like of the high reflection mirrors 41, 42. The high reflection mirrors 41, 42 are arranged such that the pulse laser light output from the laser device 3 is transmitted through the window 20 and incident on the laser light concentrating optical system 21. The beam delivery system 4 is not limited to the high reflection mirrors 41, 42 and may include other optical elements and actuators.

The laser light concentrating optical system 21 is an optical system that concentrates the pulse laser light introduced into the chamber 2 through the window 20 on the plasma generation region 26. The laser light concentrating optical system 21 is arranged in the chamber 2. The laser light concentrating optical system 21 includes a high reflection off-axis paraboloidal mirror 212, a high reflection flat mirror 213, a plate 214, and a three-axis stage 215.

Each of the high reflection off-axis paraboloidal mirror 212 and the high reflection flat mirror 213 is held by a mirror holder and fixed to the plate 214. The three-axis stage 215 is a stage with an actuator that can move the plate 214 in each of the X-axis direction, the Y-axis direction, and the Z-axis direction. Each optical element is arranged such that the concentration position of the laser light concentrating optical system 21 substantially coincides with the plasma generation region 26.

The EUV light concentrating mirror 23 is held by the EUV light concentrating mirror holder 24 and fixed to the plate 22. The plate 22 is fixed to the inner wall of the chamber 2. The plate 22 is provided with a through hole 221. The through hole 221 is a hole through which the pulse laser light reflected by the laser light concentrating optical system 21 passes toward the plasma generation region 26.

The EUV light concentrating mirror 23 has a spheroidal reflection surface. A multilayer reflective film in which molybdenum and silicon are alternately laminated is formed on the reflection surface of the EUV light concentrating mirror 23. The EUV light concentrating mirror 23 has a first focal point and a second focal point.

The EUV light concentrating mirror 23 is arranged such that the first focal point is located in the plasma generation region 26 and the second focal point is located at an intermediate focal point 28. The EUV light concentrating mirror 23 selectively reflects EUV light 262 from among the radiation light 261 that is radiated from the plasma generated at the plasma generation region 26. The EUV light concentrating mirror 23 concentrates the selectively reflected EUV light 262 on the intermediate focal point 28.

At the center of the EUV light concentrating mirror 23, a through hole 231 is provided. The through hole 231 is a hole through which the pulse laser light reflected by the laser light concentrating optical system 21 passes toward the plasma generation region 26.

Further, the EUV light generation apparatus 1 includes a connection portion 29 providing communication between the internal space of the chamber 2 and the internal space of the exposure apparatus 60. A wall in which an aperture (not shown) is formed is arranged in the connection portion 29. The aperture is arranged to be located at the second focal point of the EUV light concentrating mirror 23.

The target receiver 25 collects the targets 27 which have not been irradiated with the pulse laser light among the targets 27 output into the chamber 2 from the target generator 7. The target receiver 25 is arranged on the wall of the chamber 2 on an extension line of a target trajectory TT.

The EUV light generation control unit 5 controls the entire EUV light generation apparatus 1 based on various commands from the exposure apparatus control unit 62 of the exposure apparatus 60 which is an external apparatus. The EUV light generation control unit 5 is communicably connected with each of the laser device 3, the target control unit 6, the image processing unit 13, and the exposure apparatus control unit 62.

The EUV light generation control unit 5 controls output of the pulse laser light from the laser device 3. Further, the EUV light generation control unit 5 processes the detection result obtained from the target measurement device 9, and controls the timing at which the target 27 is output, the output direction of the target 27, and the like based on the detection result. Furthermore, the EUV light generation control unit 5 controls the oscillation timing of the laser device 3, the travel direction of the pulse laser light, the concentration position of the pulse laser light, and the like. That is, the EUV light generation control unit 5 controls the three-axis stage 215 of the laser light concentrating optical system 21. The target control unit 6 controls the target generator 7 and the two-axis stage 8 in cooperation with the EUV light generation control unit 5, and controls the output of the target 27 from the target generator 7 and the position of the target 27 supplied to the plasma generation region 26.

The above-described various kinds of control are merely examples, and other control may be added as necessary.

In the present disclosure, control units and processing units such as the EUV light generation control unit 5, the target control unit 6, the image processing unit 13, and the exposure apparatus control unit 62 are each configured using a processor. The processor is a processing device including a storage device in which a control program is stored and a central processing unit (CPU) that executes the control program. The processor is specifically configured or programmed to perform various processes included in the present disclosure.

Further, some or all of the functions of the various control units and processing units such as the EUV light generation control unit 5, the target control unit 6, the image processing unit 13, and the exposure apparatus control unit 62 may be configured to include an integrated circuit such as a field programmable gate array (FPGA) or an application specific integrated circuit (ASIC).

The functions of a plurality of control units and processing units can be realized by one unit. For example, some or all of the functions of the target control unit 6 and the image processing unit 13 may be implemented in the processor of the EUV light generation control unit 5.

Further, in the present disclosure, the plurality of control units and processing units may be connected to each other via a communication network such as a local area network or an Internet line. In a distributed computing environment, program units may be stored in both local and remote memory storage devices.

### 2.2 Operation

The operation of the EUV light generation apparatus 1 includes the following steps [1] to [17].

Step [1]: The EUV light generation apparatus 1 receives a target plasma center position Pt(Ptx, Pty, Ptz) in the plasma generation region 26 from the exposure apparatus control unit 62 via the EUV light generation control unit 5.

Step [2]: The EUV light generation control unit 5 outputs a target generation signal to the target control unit 6.

Step [3]: Upon receiving the target generation signal from the EUV light generation control unit 5, the target control unit 6 controls the target generator 7 to output the target 27 from the nozzle 72.

Although the target measurement device 9 includes two imaging devices 12 having different imaging directions, an operation of the imaging device 12 which performs imaging from a direction perpendicular to the X axis shown in FIG. 1 will be mainly described here.

Step [4]: When the target 27 output from nozzle 72 is illuminated with light from the illumination device 10, an image of the target 27 is formed by the transfer optical system 121 on the photoelectric surface PS of the image intensifier 126.

Step [5]: The light incident on the photoelectric surface PS is converted into electrons, and the electrons are incident on a microchannel plate (MCP) or the like and amplified by a potential gradient across the MCP. The space between the photoelectric surface PS and the fluorescent surface FS is vacuum.

Step [6]: The amplified electrons are converted into light on the fluorescent surface FS. The image of the target 27 on the photoelectric surface PS is also maintained on the fluorescent surface FS.

Step [7]: The image of the target 27 on the fluorescent surface FS is formed on the image sensor 128 by the transfer optical system 127.

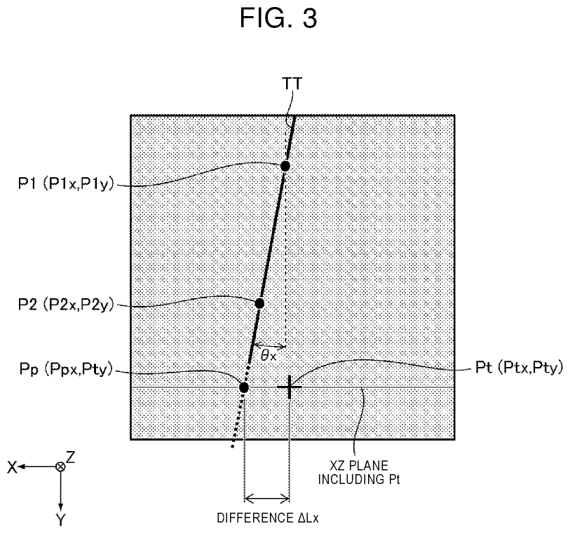

Step [8]: The image processing unit 13 performs image processing on image data of the target 27 captured by the image sensor 128. FIG. 3 shows a typical example of an image of the target 27 obtained by the imaging device 12.

Note that the image of the target 27 is measured in a granular or linear manner in accordance with the speed and frequency of the target 27 and the exposure time of the imaging device 12.

Step [9]: The image processing unit 13 first calculates at least two target passing positions P1(P1x, P1y) and P2(P2x, P2y) of the target trajectory TT from the image acquired by the imaging device 12. Next, the image processing unit 13 calculates an angle θx of the target trajectory TT with respect to the Y axis based on the target passing positions P1(P1x, P1y) and P2(P2x, P2y). Further, regarding the image data obtained by the imaging device (not shown) for imaging from a direction perpendicular to the Z axis, the image processing unit 13 calculates at least two positions P3(P3y, P3z) and P4(P4y, P4z) of the target trajectory TT by similar processing, and further, calculates an angle θz of the target trajectory TT with respect to the Y axis.

Step [10]: The image processing unit 13 transmits, to the EUV light generation control unit 5, one target passing position and the angle of the target trajectory TT with respect to the Y axis calculated from each of the image data captured from the two directions. For example, the image processing unit 13 transmits, to the EUV light generation control unit 5, the target passing position P1(P1x, P1y) and the angle θx calculated from the image captured in the X-axis direction and the target passing position P3(P3y, P3z) and the angle θz calculated from the image captured in the Z-axis direction.

Step [11]: The EUV light generation control unit 5 calculates an arrival position Pp(Ppx, Pty) of the target 27 on the XZ plane including the target plasma center position Pt from the target passing position P1(P1x, P1y) and the angle θx obtained from the image processing unit 13.

Next, the EUV light generation control unit 5 calculates an arrival position Pp(Pty, Ppz) of the target 27 on the XZ plane including the target plasma center position Pt from the target passing position P3(P3y, P3z) and the angle θz.

Step [12]: Then, the EUV light generation control unit 5 calculates the difference ΔLx=Ppx-Ptx and the difference ΔLz=Ppz-Ptz between the arrival position Pp(Ppx, Pty, Ppz) of the target trajectory TT and the target plasma center position Pt (Ptx, Pty, Ptz).

Step [13]: Thereafter, the EUV light generation control unit 5 transmits the data of the difference ΔLx and the difference ΔLz to the target control unit 6.

Step [14]: The target control unit 6 transmits a control signal to the two-axis stage 8 so that the difference ΔLx and the difference ΔLz become smaller.

Step [15]: When the oscillation trigger signal is input from the EUV light generation control unit 5 to the laser device 3, pulse laser light is output from the laser device 3. The output pulse laser light passes through the window 20 via the beam delivery system 4 and is introduced into the chamber 2.

Step [16]: The EUV light generation control unit 5 controls the three-axis stage 215 so that the concentration position of the pulse laser light by the laser light concentrating optical system 21 coincides with the center position (Ptx, Ptz) of the target plasma generation region 26.

Step [17]: The laser light concentrating optical system 21 concentrates the pulse laser light onto the target 27 which has reached the plasma generation region 26. As a result, the target 27 is turned into plasma, and the EUV light 262 is generated.

### 2.3 Problem

The space between the photoelectric surface PS and the fluorescent surface FS of the image intensifier 126 is vacuum, but residual gas is present. The electrons converted on the photoelectric surface PS of the image intensifier 126 collide with the residual gas, and the residual gas is ionized. The ionized residual gas is accelerated toward the photoelectric surface PS by the electric field.

The accelerated ionized residual gas collides with the photoelectric surface PS, and the photoelectric surface PS is deteriorated. The photoelectric surface PS is remarkably deteriorated in the portion exposed to light. When the photoelectric surface PS is deteriorated, the conversion efficiency of converting light into electrons is decreased and the brightness of the image of the target 27 on the image sensor 128 is decreased. As a result, the image becomes blurred, and the position detection accuracy of the image of the target 27 is decreased.

Although the brightness of the image of the target 27 can be increased by increasing the voltage applied to the image intensifier 126, since there is a limit to the application voltage, the brightness cannot be ensured when the application voltage becomes the maximum, and the position detection accuracy of the image of the target 27 is decreased.

When the position detection accuracy of the image of the target 27 is decreased, since the two-axis stage 8 cannot be controlled with high accuracy, it is necessary to replace the image intensifier 126 with a new one. At present, it needs to be replaced once a year. Since the image intensifier 126 is expensive, the running cost increases.

### 3. First Embodiment

### 3.1 Configuration

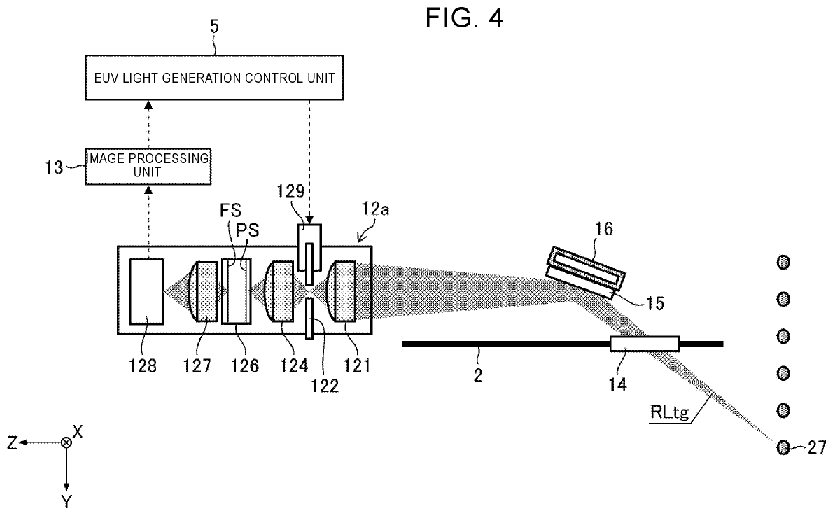

FIG. 4 schematically shows the configuration of an imaging device 12a applied to the EUV light generation apparatus 1 according to a first embodiment. FIG. 4 shows the configuration of the imaging device 12a which performs imaging from a direction perpendicular to the X axis. Here, the configuration of the imaging device which performs imaging from a direction perpendicular to the Z axis is similar to the above. Although the first embodiment shows a case in which the imaging directions of the two imaging devices are perpendicular to each other, the present embodiment is applicable as long as the imaging directions are not parallel to each other.

The EUV light generation apparatus 1 according to the first embodiment includes the imaging device 12a shown in FIG. 4 in place of the imaging device 12 described with reference to FIGS. 1 and 2. Other configurations may be similar to those in FIG. 1. The configuration shown in FIG. 4 will be described in terms of differences from the configuration shown in FIG. 2.

In the imaging device 12a, a mask 122 and a transfer optical system 124 are arranged between the transfer optical system 121 and the image intensifier 126. The mask 122 is arranged at a position where the image of the target 27 is transferred by the transfer optical system 121 (transfer position of the transfer optical system 121). The transfer optical system 124 is arranged so that the image of the target 27 at an opening of the mask 122 is transferred onto the photoelectric surface PS of the image intensifier 126. That is, the image intensifier 126 is arranged such that the photoelectric surface PS is positioned at the transfer position of the transfer optical system 124. Furthermore, the imaging device 12a includes a mask driving unit 129 which moves the mask 122.

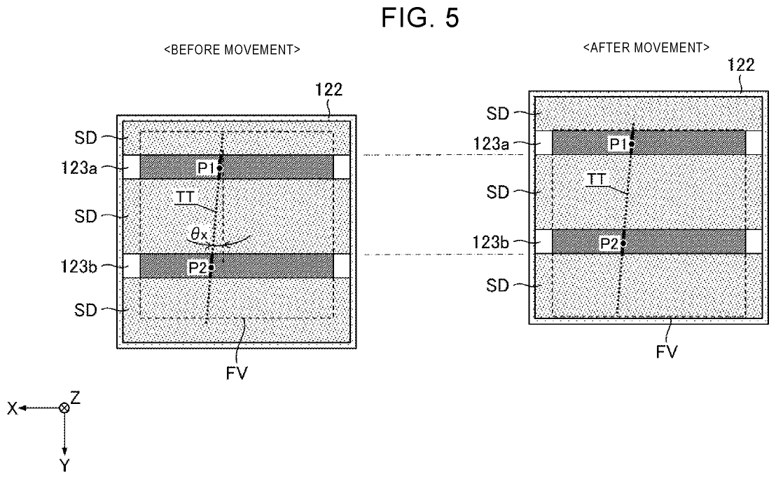

FIG. 5 shows an example of the mask 122. The left diagram of FIG. 5 shows a state (initial state) before the mask 122 is moved by the mask driving unit 129, and the right diagram of FIG. 5 shows a state after the mask 122 is moved. The mask 122 exemplified in FIG. 5 has at least two openings 123a, 123b. Each of the openings 123a, 123b has a rectangular shape with a long side in the X-axis direction and a short side in the Y-axis direction. Note that the shape of the openings 123a, 123b is not limited to a rectangle, and may be a rounded rectangle, or may be, for example, a horizontally long ellipse or an oval with a major axis in the X-axis direction and a minor axis in the Y-axis direction.

A rectangular region FV indicated by a broken line in FIG. 5 represents a view field region of the imaging device 12a. The view field region FV may be understood as a region corresponding to the region of the photoelectric surface PS of the image intensifier 126.

The long sides of the openings 123a, 123b may be longer than the length of the view field region FV in the X-axis direction. It is preferable that the short sides of the openings 123a, 123b are as short as possible because the deterioration area of the photoelectric surface PS becomes small. Further, it is preferable that the two openings 123a, 123b are separated from each other as much as possible because the detection accuracy of the angle of the target trajectory TT becomes high.

The shape of the opening 123a and the shape of the opening 123b may be the same. It is desirable that the size of the openings 123a, 123b is smaller than the size of a light shielding portion SD. The area of one opening 123a (or 123b) is, for example, 1/10 to ¼ of the area of the entire view field of the imaging device 12a. Note that the opening 123a and the opening 123b may have different shapes. The material of the mask 122 may be, for example, glass with stainless steel or a tantalum or chromium film.

The mask driving unit 129 may be, for example, a linear stage including an actuator. The operation of the mask driving unit 129 is controlled by the EUV light generation control unit 5. The mask driving unit 129 moves the mask 122 in the Y-axis direction. By moving the mask 122 in the Y-axis direction, the openings 123a, 123b can be moved in the Y-axis direction to change the region on the photoelectric surface PS on which light is incident. For example, when the lifetime of the image intensifier 126 due to deterioration is about one year, the mask 122 is moved at intervals of about one year.

The transfer optical system 121 is an example of the “first transfer optical system” in the present disclosure. The mask driving unit 129 is an example of the “moving mechanism” in the present disclosure. The transfer optical system 124 is an example of the “second transfer optical system” in the present disclosure. The transfer optical system 127 is an example of the “third transfer optical system” in the present disclosure.

### 3.2 Operation

The operation of the EUV light generation apparatus 1 according to the first embodiment will be described with respect to differences from the operation of the EUV light generation apparatus 1 according to the comparative example. The operation of steps [1] to [3] is included in the operation of the EUV light generation apparatus 1 according to the first embodiment. The EUV light generation apparatus 1 according to the first embodiment includes the operation of the following steps [1A] to [11A].

Step [1A]: The image of the target 27 by reflection light RLtg from the target 27 illuminated by the illumination device 10 is transferred onto the mask 122 by the transfer optical system 121.

Step [2A]: Light having reached the light shielding portion SD, which is a portion other than openings 123a, 123b of the mask 122, is shielded and absorbed by the light shielding portion SD.

Step [3A]: The image of the target 27 by the light on the openings 123a, 123b of the mask 122 is transferred onto the photoelectric surface PS of the image intensifier 126 by the transfer optical system 124.

Step [4A]: The light of the image of the target 27 in the region shielded by the mask 122 does not reach the photoelectric surface PS of the image intensifier 126. The light of the image of the target 27 having reached the photoelectric surface PS of the image intensifier 126 is converted into electrons, and the electrons are amplified in the image intensifier 126.

Step [5A]: The amplified electrons reach the fluorescent surface FS of the image intensifier 126 and are converted into light.

Step [6A]: The image of the target 27 on the fluorescent surface FS is transferred onto the image sensor 128 by the transfer optical system 127.

Step [7A]: The image of the target 27 is obtained by the image sensor 128. However, the image of the target 27 is not obtained in the region shielded by the light shielding portion SD of the mask 122.

Step [8A]: The image data obtained by the imaging device 12a is transmitted to the image processing unit 13.

In the image processing unit 13, the target passing positions P1(P1x, P1y) and P2(P2x, P2y) of the two openings 123a, 123b of the mask 122 and the angle θx of the target trajectory TT with respect to the Y axis are calculated from the image data. Similarly, the target passing positions P3(P3y, P3z) and P4(P4y, P4z) and the angle θz of the target trajectory TT with respect to the Y axis are calculated from the image data obtained from the imaging device which captures from the direction perpendicular to the Z axis.

Step [9A]: The subsequent operation is the same as steps [10] to [17] of the EUV light generation apparatus 1 according to the comparative example.

Step [10A]: Then, after being used for a certain period of time, for example, after one year, the openings 123a, 123b of the mask 122 are moved in the Y-axis direction by the mask driving unit 129 to positions which are not overlapped with the regions of the openings 123a, 123b before the movement.

Step [11A]: After moving the mask 122, the operation of the steps [1A] to [10A] is performed, the operation of the step [10A] being performed after the operation for a certain period of time.

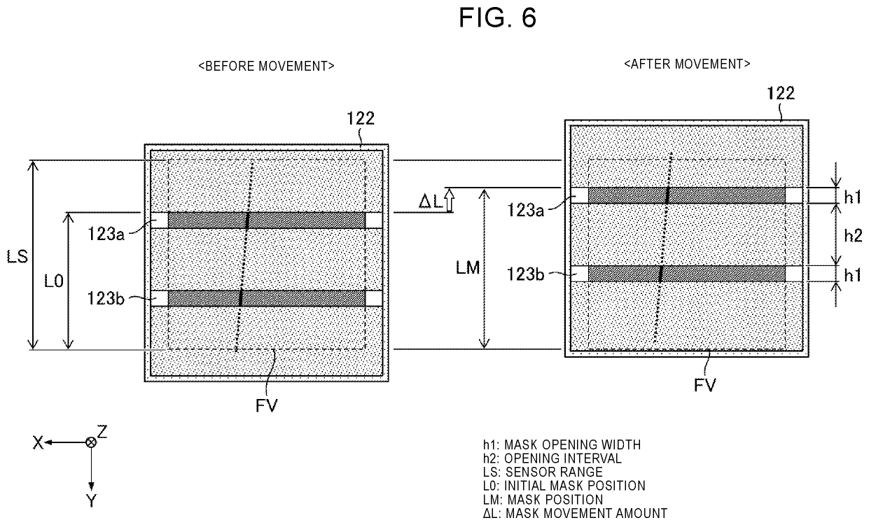

The movement amount and the maximum number of movements of the mask 122 can be set based on the relationship between the shapes of the openings 123a, 123b of the mask 122 and the view field range (sensor range) of the image sensor 128. FIG. 6 shows the definition of each parameter related to the mask 122. As shown in FIG. 6, when the width (mask opening width) of the openings 123a, 123b of the mask 122 in the Y-axis direction is h1, the opening distance is h2, the sensor range is LS, the initial mask position is L0, the mask movement amount in one mask movement is ΔL, the mask movement number is n, the mask position after n mask movements is LM, and the maximum number of mask movements is N, the mask position LM is expressed by LM=L0+n×ΔL. In order to prevent the openings 123a, 123b after the movement from being overlapped with the regions of the openings 123a, 123b before the movement, the mask movement amount ΔL is required to be equal to or larger than h1. In this case, the maximum mask movement number N is a maximum integer equal to or smaller than (LS−L0)/ΔL and equal to or smaller than h2/ΔL.

The initial mask position L0 shown in the left diagram of FIG. 6 is an example of the “first position” in the present disclosure, and the mask position LM after the mask movement shown in the right diagram of FIG. 6 is an example of the “second position” in the present disclosure.

### 3.3 Mask Movement Control Method

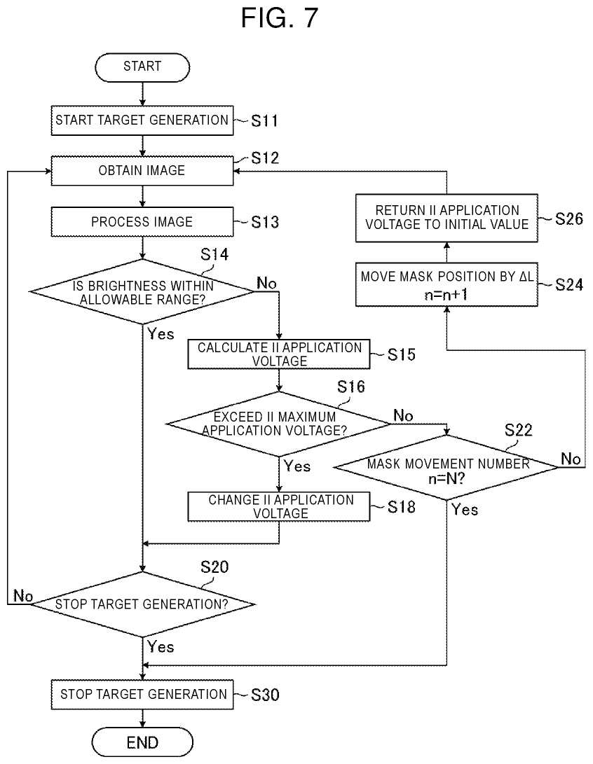

FIG. 7 is a flowchart showing an example of a mask movement control method in the EUV light generation apparatus 1 according to the first embodiment. Each step of the flowchart shown in FIG. 7 can be executed by a processor functioning as the EUV light generation control unit 5 and/or the image processing unit 13 based on a program.

In step S11, the EUV light generation control unit 5 controls the target generator 7 via the target control unit 6 to start generating the target 27.

In step S12, the image of the target 27 is captured using the imaging device 12a, and image data of the image of the target 27 is obtained from the imaging device 12a.

In step S13, the image processing unit 13 performs processing of the image data obtained via the imaging device 12a, and calculates the brightness in the image data. The brightness calculated by the image processing unit 13 may be the maximum or average brightness.

In step S14, the EUV light generation control unit 5 determines whether or not the calculated brightness is within an allowable range. When the brightness is higher than the upper limit of the allowable range, there is a possibility to accelerate deterioration of the image intensifier 126. When the brightness is lower than the lower limit of the allowable range, there is a possibility to decrease position detection accuracy of the target 27.

When the determination result in step S14 is Yes (when the brightness is within the allowable range), the EUV light generation control unit 5 proceeds to step S20.

In step S20, the EUV light generation control unit 5 determines whether or not to end generating the target 27. The EUV light generation control unit 5 performs determination in step S20 based on presence or absence of a target generation end signal.

When the determination result in step S20 is Yes (when the target generation end signal exists), the EUV light generation control unit 5 proceeds to step S30 and stops the target generation.

On the other hand, when the determination result in step S20 is No (when there is no target generation end signal), the EUV light generation control unit 5 returns to step S12.

When the determination result in step S14 is No (when the brightness is outside the allowable range), the EUV light generation control unit 5 proceeds to step S15. In step S15, the EUV light generation control unit 5 calculates the application voltage to the image intensifier 126 (hereinafter, referred to as “II application voltage”) so that the brightness falls within the allowable range.

Then, in step S16, the EUV light generation control unit 5 determines whether or not the II application voltage as the calculated result exceeds the maximum application voltage (hereinafter referred to as “II maximum application voltage”). When the determination result in step S16 is No (when the II application voltage as the calculated result does not exceed the II maximum application voltage), the EUV light generation control unit 5 proceeds to step S18.

In step S18, the EUV light generation control unit 5 changes the voltage to be applied to the image intensifier 126 to the calculated II application voltage, and then proceeds to step S20.

When the determination result in step S16 is Yes (when the II application voltage as the calculated result exceeds the II maximum application voltage), the EUV light generation control unit 5 proceeds to step S22. The II maximum application voltage serving as a determination criterion is an example of the “predetermined value” in the present disclosure.

In step S22, the EUV light generation control unit 5 determines whether or not the mask movement number n is equal to the maximum mask movement number N. Here, the initial value of the mask movement number n is 0. The maximum mask movement number N is a maximum integer equal to or smaller than (LS−L0)/ΔL and equal to or smaller than h2/ΔL.

When the determination result in step S22 is No (when the mask movement number n is not the same value as the maximum mask movement number N), the EUV light generation control unit 5 proceeds to step S24.

In step S24, the EUV light generation control unit 5 moves the mask 122 by the mask movement amount ΔL, and updates the value of n by incrementing the mask movement number n by 1.

Then, in step S26, the EUV light generation control unit 5 returns the II application voltage to the initial value and returns to step S12.

On the other hand, when the determination result in step S22 is Yes (when the mask movement number n is the same value as the mask maximum movement number N), the EUV light generation control unit 5 determines that the mask 122 cannot be moved anymore and proceeds to step S30 to stop the target generation. After step S30, the flowchart of FIG. 7 ends.

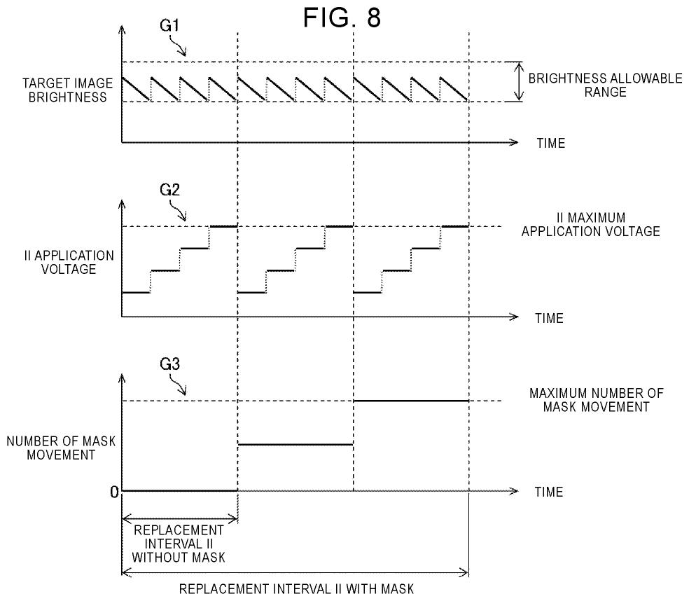

FIG. 8 is a graph schematically showing an example of the operation of the imaging device 12a based on the control of the flowchart of FIG. 7. The graph G1 shown in the upper part of FIG. 8 shows the transition of brightness of the image of the target 27 captured by the imaging device 12a. The graph G2 shown in the middle part of FIG. 8 shows the transition of the II application voltage. The graph G3 shown in the lower part of FIG. 8 shows the transition of the movement number of the mask 122.

FIG. 8 shows an example in which the maximum mask movement number N is 2. The period in which the mask movement number n is 0 corresponds to the period in which the mask 122 is used as being positioned in the initial state. After the start of use, a part of the photoelectric surface PS of the image intensifier 126 is deteriorated with the lapse of time and the target image brightness is decreased. When the target image brightness becomes lower than the allowable range, the II application voltage is increased to adjust the target image brightness so as to fall within the allowable range. The adjustment of the target image brightness is performed by such adjustment of the application voltage until the II application voltage reaches the II maximum application voltage. Since the II application voltage cannot exceed the II maximum application voltage, when the II application voltage is about to exceed the II maximum application voltage, the mask 122 is moved to change the positions of openings 123a, 123b with respect to the photoelectric surface PS.

Since the configuration of the comparative example (FIG. 1) does not include the mask 122, the image intensifier 126 must be replaced when the II application voltage is about to exceed the II maximum application voltage. On the other hand, in the EUV light generation apparatus 1 according to the first embodiment, by moving the mask 122, the use thereof can be continued without replacing the image intensifier 126. According to the example of FIG. 8, the replacement interval may be about three times the replacement interval of the image intensifier 126 in the comparative example, that is, the replacement frequency may be about ⅓.

### 3.4 Effects

According to the first embodiment, since the mask 122 is arranged at the position where the image of the target 27 by the target reflection light RLtg is transferred by the transfer optical system 121, only the region where the openings 123a, 123b of the mask 122 are transferred in the photoelectric surface PS of the image intensifier 126 is deteriorated, and the region where the light shielding portion SD of the mask 122 is transferred is less likely to be deteriorated.

By moving openings 123a, 123b of the mask 122, the region of the photoelectric surface PS to which the new region of the openings 123a, 123b is transferred is in mint condition, so that the position of the image of the target 27 can be measured without lowering the detection accuracy.

When the two openings 123a, 123b of the mask 122 are configured to open 1/K of the area of the entire view field, the frequency of replacing the image intensifier 126 may be 1/K compared to the comparative example. Here, K is an integer of 2 or larger, preferably 2 or larger and 5 or smaller. Further, by separating the distances in the Y-axis direction between the two openings 123a, 123b (opening interval h2) as much as possible, the accuracy of the angles θx, θz can be made equivalent to that of the EUV light generation apparatus 1 according to the comparative example.

### 3.5 Modification of Target Measurement Device

The imaging device 12a shown in FIG. 4 is configured to receive the reflection light RLtg from the target 27, but may be configured such that the illumination device 10 is arranged at a position facing the imaging device 12a and the transmission light passing through the target trajectory TT is incident on the imaging device 12a. In this case, the imaging device 12a will captures the image of the target 27 as a dark portion (shadow). When employing such a backlight type configuration, the illumination device and the imaging device are arranged in pair (set). Therefore, in order to capture images from at least two imaging directions, at least two illumination devices and at least two imaging devices are arranged.

The operation of steps [1A] to [11A] and the operation of the flowchart of FIG. 7 are the same even when the illumination device 10 arranged at a position facing the imaging device 12a is used. In addition, the operation and effect in the case of using the illumination device 10 arranged at a position facing the imaging device 12a are also the same as those in the first embodiment.

### 3.6 Modification of Mask Driving Unit

Although FIG. 4 exemplifies the configuration in which the mask driving unit 129 is controlled by the EUV light generation control unit 5, the mechanism for moving the mask 122 is not limited to an automatically controlled configuration and may be a mechanism for manually moving the mask 122. For example, instead of the mask driving unit 129, a mechanism in which a micrometer and a linear stage are combined may be used.

### 3.7 Modification of Mask

### 3.7.1 Configuration

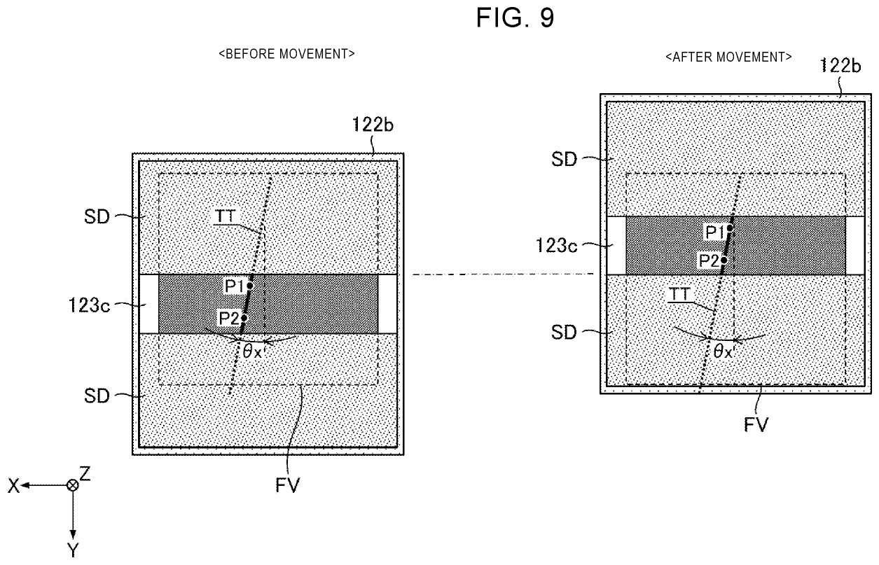

FIG. 9 shows an example of the mask 122. The imaging device 12a may include a mask 122b shown in FIG. 9 instead of the mask 122 described with reference to FIGS. 5 and 6. The configuration shown in FIG. 9 will be described in terms of differences from the mask 122 shown in FIGS. 5 and 6.

The mask 122 has two openings 123a, 123b, whereas the mask 122b shown in FIG. 9 has only one opening 123c. Although FIG. 9 shows the mask 122b having a rectangular opening 123c with a short side in the Y-axis direction, the shape of the opening 123c is not limited to a rectangle, and may be a rounded rectangle, a horizontally long ellipse, an oval, or the like.

Since the accuracy of the angle θx is deteriorated when the distance between the target passing positions P1, P2 transferred into the region of the opening 123c becomes short, it is preferable that the short side of the opening 123c of the mask 122b is set as long as possible. The area of the opening 123c is, for example, ⅕ to ½ of the area of the entire view field of the imaging device 12a. Other configurations may be similar to those in the first embodiment.

### 3.7.2 Operation

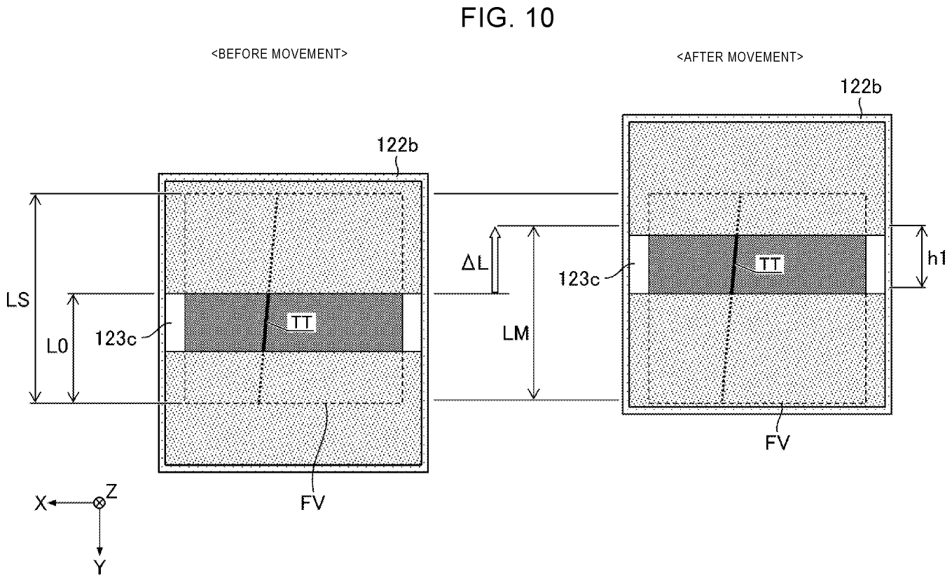

The operation of the EUV light generation apparatus 1 including the imaging device 12a provided with the mask 122b is similar to that of the first embodiment. The difference from the first embodiment is in the maximum mask movement number N. When each parameter for the mask 122b is defined as shown in FIG. 10, the maximum mask movement number N is the maximum integer equal to or smaller than (LS−L0)/ΔL.

### 3.7.3 Effects

In the imaging device 12a provided with the mask 122b, since the mask 122b is arranged at the position where the image of the target 27 by the target reflection light RLtg is transferred by the transfer optical system 121, only the region where the opening 123c of the mask 122b is transferred in the photoelectric surface PS of the image intensifier 126 is deteriorated, and the region where the light shielding portion SD of the mask 122b is transferred is less likely to be deteriorated.

By moving the opening 123c of the mask 122b, the region of the photoelectric surface PS to which the new region of the opening 123c is transferred is in mint condition, so that the position of the image of the target 27 can be measured without lowering the detection accuracy.

When the opening 123c of the mask 122 is configured to open 1/K of the region of the entire view field, the frequency of replacing the image intensifier 126 is 1/K compared to the comparative example.

Since the mask 122b of FIG. 9 has a simpler structure than the mask 122 of FIG. 5, the manufacturing cost can be reduced. Further, the operation and effect of the configuration in which the illumination device 10 is arranged at the position facing the imaging device 12a are also the same as those in the first embodiment.

### 4. Second Embodiment

### 4.1 Configuration

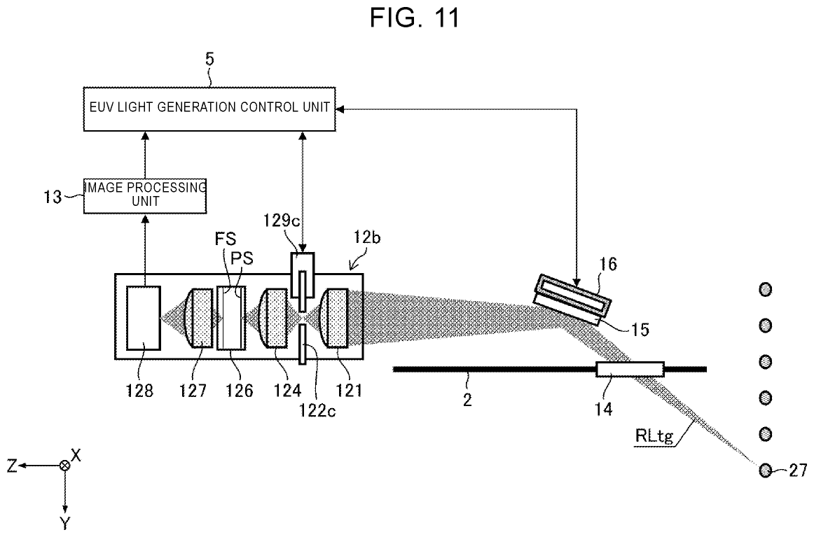

FIG. 11 schematically shows the configuration of an imaging device 12b applied to the EUV light generation apparatus 1 according to a second embodiment. FIG. 11 shows an example of the imaging device 12b which performs imaging from the direction perpendicular to the X axis. The configuration of the imaging device 12b will be described in terms of differences from the imaging device 12a in the first embodiment. In the second embodiment, the EUV light generation control unit 5 outputs a control signal to the two-axis stage 16 to control the two-axis stage 16. Further, the imaging device 12b includes a mask 122c instead of the mask 122. The high reflection mirror 15 which reflects the target reflection light RLtg and changes the travel direction of the target reflection light RLtg is an example of the “mirror” in the present disclosure. The two-axis stage 16 is an example of the “mirror adjustment mechanism” in the present disclosure.

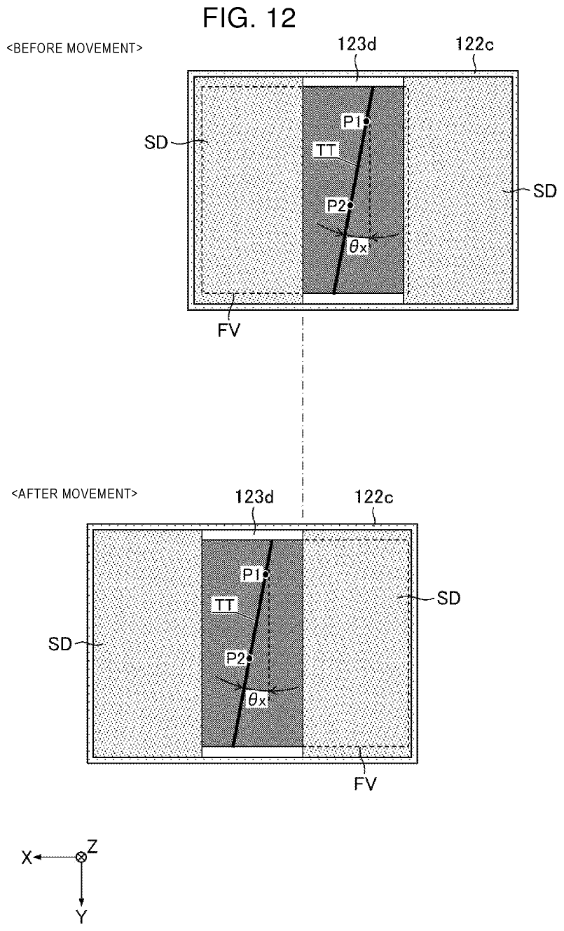

FIG. 12 shows the configuration of the mask 122c applied to the second embodiment. The difference from the mask 122 of the first embodiment is that the mask 122c has one opening 123d and the opening 123d is a rectangle having a long side in the Y-axis direction and a short side in the X-axis direction. The long side of the opening 123d may be longer than the length of the view field region FV in the Y-axis direction. The short side of the opening 123d preferably has a length such that the entire image of the target trajectory TT can be obtained. The area of the opening 123d is, for example, ⅓ to ½ of the area of the entire view field of the imaging device 12b.

Further, the imaging device 12b includes a mask driving unit 129c instead of the mask driving unit 129. The mask driving unit 129c includes a mechanism for moving the mask 122c in the X-axis direction. Other configurations may be similar to those of the first embodiment.

### 4.2 Operation

The operation of the second embodiment includes the following steps [1B] to [4B].

Step [1B]: The EUV light generation apparatus 1 according to the second embodiment operates in the same manner as steps [1A] to [9A] of the first embodiment.

Step [2B]: After being used for a certain period of time, for example, after one year, the opening 123d of the mask 122c is moved in the Y-axis direction by the mask driving unit 129c to a position which is not overlapped with the opening 123d before the movement.

Step [3B]: Then, the orientation of the high reflection mirror 15 is adjusted by the two-axis stage 16 so that the image of the target 27 is transferred into the region of the moved opening 123d.

Step [4B]: After adjusting with the two-axis stage 16, the operation of the step [1B] (operation of the step [1A] to [9A]) may be performed. Then, after a certain period of time of use, the operation of steps [2B] and [3B] is performed.

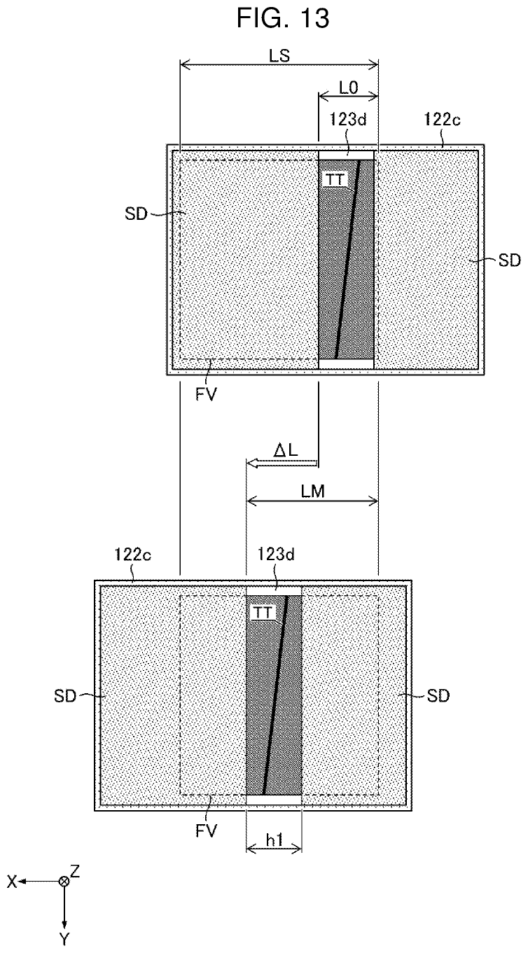

When each parameter for the mask 122c is defined as shown in FIG. 13, in the case of the mask 122c, the maximum mask movement number N is the maximum integer equal to or smaller than (LS−L0)/ΔL.

### 4.3 Mask Movement Control Method

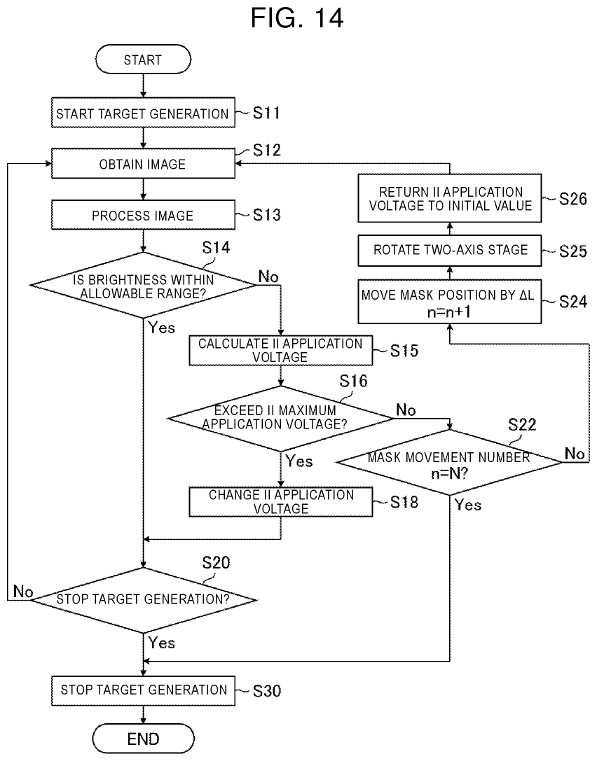

FIG. 14 is a flowchart showing an example of the mask movement control method in the EUV light generation apparatus 1 according to the second embodiment. The flowchart shown in FIG. 14 will be described in terms of differences from that shown in FIG. 7. The flowchart of FIG. 14 includes step S25 between step S24 and step S26. The maximum mask movement number N applied to the determination in step S22 is the maximum integer equal to or smaller than (LS−L0)/ΔL. Other steps may be similar to those in FIG. 7.

In step S24, the EUV light generation control unit 5 moves the mask 122c in the X-axis direction by the mask movement amount ΔL, and updates the value of n by incrementing the mask movement number n by 1, and then proceeds to step S25.

In step S25, the EUV light generation control unit 5 rotates the two-axis stage 16 so that the position of the target image is changed by the same amount as the change in the position of the opening 123d due to the movement of the mask 122c.

Then, in step S26, the EUV light generation control unit 5 returns the II application voltage to the initial value and returns to step S12.

### 4.4 Effects

According to the second embodiment, since the mask 122c is arranged at the position where the image of the target 27 by the reflection light Rltg of the target 27 is transferred by the transfer optical system 121, only the region where the opening 123d of the mask 122c is transferred in the photoelectric surface PS of the image intensifier 126 is deteriorated, and the region where the light shielding portion SD of the mask 122c is transferred is less likely to be deteriorated. When the illumination device 10 is arranged so as to detect the reflection light RLtg, the entire target image enters the opening 123d and the target image is not shielded by the mask 122c. However, due to the presence of the mask 122c, the scattered light is shielded by the light shielding portion SD, and deterioration of the region to which the light shielding portion SD is transferred can be reduced.

By moving the opening 123d of the mask 122c, the region of the photoelectric surface PS to which the new region of the opening 123d is transferred is in mint condition, so that the position of the image of the target 27 can be measured without lowering the detection accuracy.

For example, when the area of the opening 123d of the mask 122c is ½ of the entire view field, the frequency of replacing the image intensifier 126 is ½ compared to the comparative example.

According to the second embodiment, since the target passing position P1 and the target passing position P2 can be the same as in the comparative example, the accuracy of the angle θx or θz can be the same as that of the device of the comparative example.

### 4.5 Modification of Target Measurement Device

The imaging device 12b shown in FIG. 11 is configured to receive the reflection light RLtg from the target 27, but may be configured such that the illumination device 10 is arranged at a position facing the imaging device 12b and the transmission light passing through the target trajectory TT is incident on the imaging device 12b. The operation of steps [1B] to [4B] and the operation of the flowchart of FIG. 14 are the same even when the illumination device 10 arranged at a position facing the imaging device 12b is used. In addition, the operation and effect in the case of using the illumination device 10 arranged at a position facing the imaging device 12b are also the same as those in the second embodiment. The second embodiment is particularly effective in the case of using the illumination device 10 arranged at the position facing the imaging device 12b.

### 4.6 Modification of Mask

### 4.6.1 Configuration

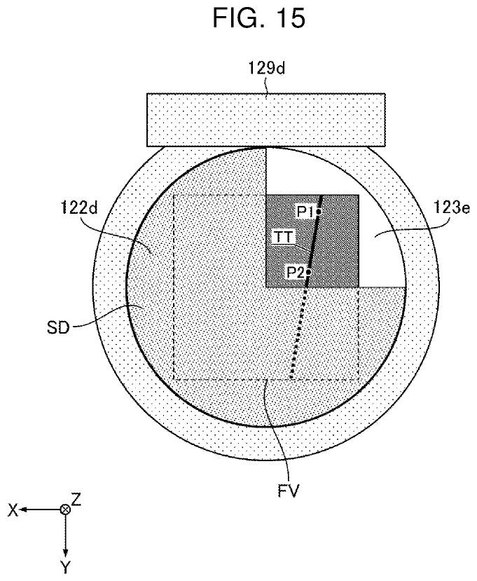

FIG. 15 shows a modification of the mask 122c. Instead of the mask 122c and the mask driving unit 129c described with reference to FIGS. 11 and 12, a mask 122d and a mask driving unit 129d shown in FIG. 15 may be used. The configuration shown in FIG. 15 will be described in terms of differences from the configuration shown in FIGS. 11 and 12.

The mask 122d has a circular outer shape, and the shape of the opening 123e is a quadrant (¼ circle). Note that the opening 123e may be a notch. The mask driving unit 129d is configured using a rotation stage and rotates the mask 122d around the center of the circle. The size of the mask 122d is larger than the entire range of the view field region FV. Other configurations may be similar to those of the second embodiment.

### 4.6.2 Operation

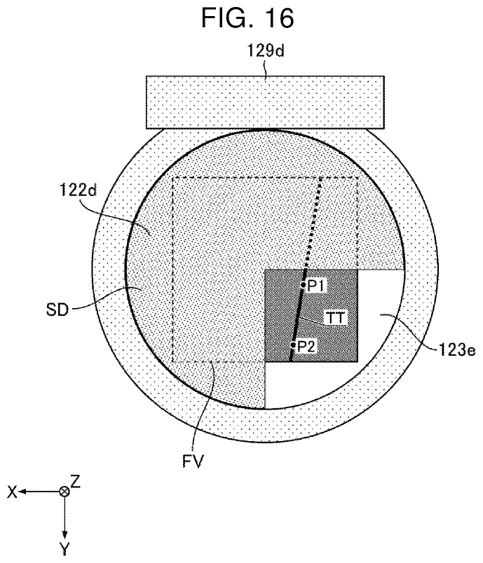

FIG. 15 shows a state before the mask 122d is moved (initial state), and FIG. 16 shows a state after the mask 122d is rotated by 90°.

The operation of the EUV light generation apparatus 1 using the mask 122d is similar to that of the second embodiment. The difference from the second embodiment is in the movement direction of the mask 122d, the mask movement amount ΔL, and the maximum mask movement number N.

After a certain period of time of use, for example, after one year, the opening 123e of the mask 122d is rotated to a position which is not overlapped with the opening 123e before the movement (see FIG. 16). Then, the high reflection mirror 15 is adjusted by the two-axis stage 16 so that the image of the target 27 is transferred to the region of the opening 123e after the movement.

After the mask 122d and the two-axis stage 16 are moved, step [1B] is performed, and the operation of step [2B] and step [3B] is performed after a certain period of time of use.

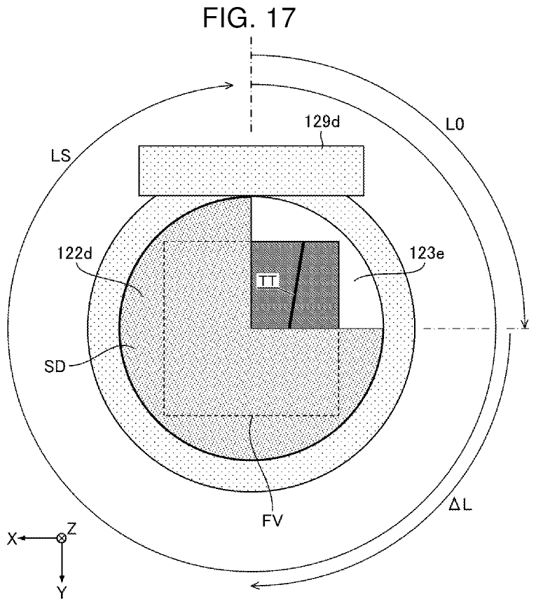

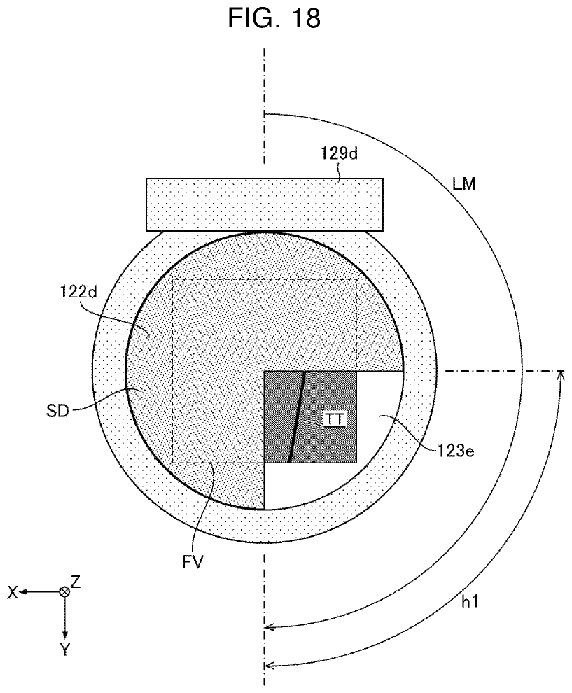

FIGS. 17 and 18 show the definition of each parameter related to the mask 122d. FIG. 17 shows a state before the mask 122d is moved, and FIG. 18 shows a state after the mask 122d is moved.

In the case of the circular mask 122d, the mask opening width h1, the sensor range LS, the initial mask position L0, the mask position LM, and the mask movement amount ΔL can be represented by angles. FIGS. 17 and 18 show an example in which the mask opening width h1 is 90°, the sensor range LS is 360°, the initial mask position L0 is 90°, the mask movement amount ΔL is 90°, the mask movement number n is 0 to 3, and the maximum mask movement number N is 3.

The flowchart of FIG. 14 can be applied to the method for automatically controlling the movement of the mask 122d.

### 4.6.3 Effects

In the imaging device 12b provided with the mask 122b and the mask driving unit 129d, since the mask 122d is arranged at the position where the image of the target 27 by the target reflection light RLtg is transferred by the transfer optical system 121, only the region where the opening 123e of the mask 122d is transferred in the photoelectric surface PS of the image intensifier 126 is deteriorated, and the region where the light shielding portion SD of the mask 122d is transferred is less likely to be deteriorated.

By moving the opening 123e of the mask 122d, the region of the photoelectric surface PS to which the new region of the opening 123e is transferred is in mint condition, so that the position of the image of the target 27 can be measured without lowering the detection accuracy.

In the case of the mask 122d shown in FIGS. 15 to 18, since the size of the opening 123e is ¼ of the area of the entire view field, the frequency of replacing the image intensifier 126 is ¼ compared to the comparative example.

### 5. Regarding Mask Replacement

In the first and second embodiments described above, description has been provided on an example in which the position of the opening (open region) with respect to the photoelectric surface PS of the image intensifier 126 is changed by moving the mask 122 122a, 122b, 122c, or 122d having the opening. However, as a method of changing the position of the opening with respect to the photoelectric surface PS, the mask itself may be changed to another one. For example, by preparing a plurality of types of masks having different opening positions so that the regions of the openings are not overlapped with each other in different masks, and replacing the mask after using a specific mask for a certain period of time, the position of the opening can be changed so that the regions of the opening are not overlapped before and after the replacement. In this case, for example, instead of the mask driving unit 129, a mask attachment/detachment mechanism or the like may be arranged as a mechanism for replacing the mask.

### 6. Electronic Device Manufacturing Method

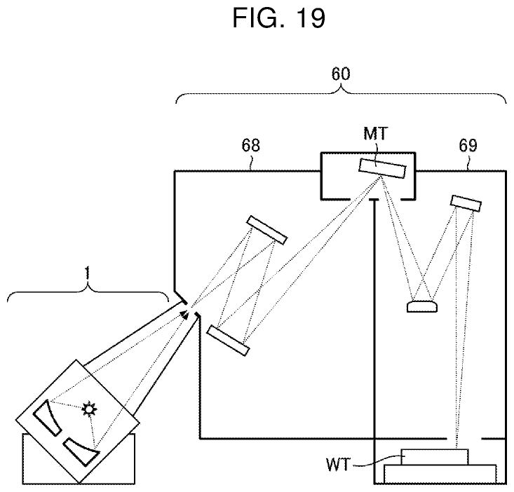

FIG. 19 schematically shows the configuration of the exposure apparatus 60 connected to the EUV light generation apparatus 1. The exposure apparatus 60 includes a mask irradiation unit 68 and a workpiece irradiation unit 69. The mask irradiation unit 68 illuminates, via a reflection optical system, a mask pattern of a reticle table MT with EUV light incident from the EUV light generation apparatus 1. The workpiece irradiation unit 69 images the EUV light reflected by the reticle table MT onto a workpiece (not shown) placed on the workpiece table WT through a reflection optical system. The workpiece is a photosensitive substrate such as a semiconductor wafer on which photoresist is applied.

The exposure apparatus 60 synchronously translates the reticle table MT and the workpiece table WT to expose the workpiece to the EUV light reflecting the reticle pattern. Through the exposure process as described above, a device pattern is transferred onto the semiconductor wafer, thereby an electronic device can be manufactured.

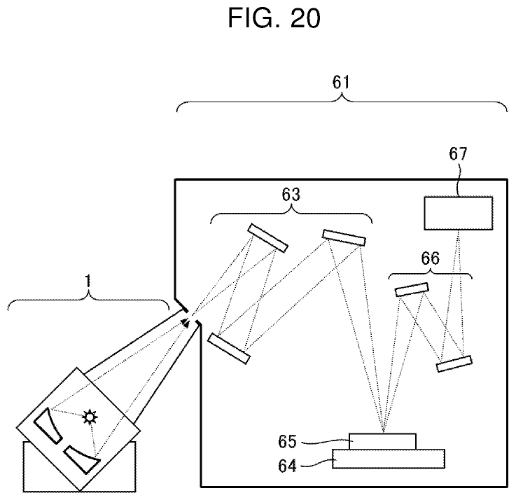

FIG. 20 schematically shows the configuration of an inspection device 61 connected to the EUV light generation apparatus. The inspection device 61 includes an illumination optical system 63 and a detection optical system 66. The illumination optical system 63 reflects the EUV light incident from the EUV light generation apparatus 1 to illuminate a reticle 65 placed on a reticle stage 64. Here, the reticle 65 conceptually includes a mask blank before a pattern is formed. The detection optical system 66 reflects the EUV light from the illuminated reticle 65 and forms an image on a light receiving surface of a detector 67. The detector 67 having received the EUV light obtains the image of the reticle 65. The detector 67 is, for example, a time delay integration (TDI) camera. Defects of the reticle 65 are inspected based on the image of the reticle 65 obtained by the above-described process, and a reticle suitable for manufacturing an electronic device is selected using the inspection result. Then, the electronic device can be manufactured by exposing and transferring the pattern formed on the selected reticle onto the photosensitive substrate using the exposure apparatus 60.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation apparatus, comprising:
a chamber in which a target supplied to a plasma generation region at inside thereof is turned into plasma and extreme ultraviolet light is generated;
a target generator configured to supply the target to the plasma generation region in the chamber;
an illumination device connected to the chamber and configured to output illumination light toward the target supplied from the target generator; and
an imaging device connected to the chamber and configured to receive the illumination light and capture an image of the target,
the imaging device including:
a first transfer optical system configured to transfer the image of the target;
a mask having an opening formed at a transfer position of the first transfer optical system;
a second transfer optical system configured to transfer the image of the target at the opening;
an image intensifier having a photoelectric surface and a fluorescent surface and arranged such that the photoelectric surface is located at a transfer position of the second transfer optical system;
a third transfer optical system configured to transfer the image of the target at the fluorescent surface;
an image sensor arranged at a transfer position of the third transfer optical system and configured to capture the image of the target transferred by the third transfer optical system; and
a moving mechanism capable of moving the mask by an amount equal to or larger than the opening.

2. The extreme ultraviolet light generation apparatus according to claim 1,
wherein the imaging device receives reflection light of the illumination light from the target.

3. The extreme ultraviolet light generation apparatus according to claim 1,
wherein the imaging device receives transmission light of the illumination light having passed through a trajectory of the target.

4. The extreme ultraviolet light generation apparatus according to claim 1,
wherein the opening is smaller than a light shielding portion which is a region of the mask excluding the opening.

5. The extreme ultraviolet light generation apparatus according to claim 1,
wherein a movement direction of the mask by the moving mechanism is parallel to a travel direction of the target.

6. The extreme ultraviolet light generation apparatus according to claim 5,
wherein a length of the opening in the movement direction is shorter than a length of the opening in a direction perpendicular to the movement direction.

7. The extreme ultraviolet light generation apparatus according to claim 5,
wherein the opening has a rectangular shape.

8. The extreme ultraviolet light generation apparatus according to claim 5,
wherein the mask has at least two of the openings.

9. The extreme ultraviolet light generation apparatus according to claim 1,
wherein the mask is moved from a first position to a second position by the moving mechanism, and the opening of the mask located at the second position is not overlapped with the opening of the mask located at the first position.

10. The extreme ultraviolet light generation apparatus according to claim 1,
further comprising:
a mirror arranged between the chamber and the imaging device to change a travel direction of the illumination light, and
a mirror adjustment mechanism configured to adjust orientation of the mirror,
wherein, after the mask is moved by the moving mechanism, the orientation of the mirror is adjusted by the mirror adjustment mechanism so that the image of the target transferred by the first transfer optical system passes through the opening.

11. The extreme ultraviolet light generation apparatus according to claim 10,
wherein a movement direction of the mask by the moving mechanism is perpendicular to a travel direction of the target.

12. The extreme ultraviolet light generation apparatus according to claim 11,
wherein a length of the opening in the movement direction is shorter than a length of the opening in a direction perpendicular to the movement direction.

13. The extreme ultraviolet light generation apparatus according to claim 1,
wherein the moving mechanism is a mechanism which rotates the mask about a center of the mask.

14. The extreme ultraviolet light generation apparatus according to claim 13,
wherein the shape of the opening is a quadrant.

15. The extreme ultraviolet light generation apparatus according to claim 1,
further comprising a processor configured to control operation of the moving mechanism.

16. The extreme ultraviolet light generation apparatus according to claim 15,
wherein the processor operates the moving mechanism to move the mask when a voltage applied to the image intensifier exceeds a predetermined value.

17. The extreme ultraviolet light generation apparatus according to claim 15,
wherein the processor operates the moving mechanism to move the mask when brightness of the image of the target captured by the image sensor is outside an allowable range.

18. An imaging device configured to capture an image of a target supplied from a target generator while receiving illumination light radiated to the target, comprising:
a first transfer optical system configured to transfer the image of the target;
a mask having an opening formed at a transfer position of the first transfer optical system;
a second transfer optical system configured to transfer the image of the target at the opening;
an image intensifier having a photoelectric surface and a fluorescent surface and arranged such that the photoelectric surface is located at a transfer position of the second transfer optical system;
a third transfer optical system configured to transfer the image of the target at the fluorescent surface;
an image sensor arranged at a transfer position of the third transfer optical system and configured to capture the image of the target transferred by the third transfer optical system; and
a moving mechanism capable of moving the mask by an amount equal to or larger than the opening.

19. An electronic device manufacturing method, comprising:
generating extreme ultraviolet light using an extreme ultraviolet light generation apparatus;
emitting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a chamber in which a target supplied to a plasma generation region at inside thereof is turned into plasma and the extreme ultraviolet light is generated;
a target generator configured to supply the target to the plasma generation region in the chamber;
an illumination device connected to the chamber and configured to output illumination light toward the target supplied from the target generator; and
an imaging device connected to the chamber and configured to receive the illumination light and capture an image of the target, and
the imaging device including:
a first transfer optical system configured to transfer the image of the target;
a mask having an opening formed at a transfer position of the first transfer optical system;
a second transfer optical system configured to transfer the image of the target at the opening;
an image intensifier having a photoelectric surface and a fluorescent surface and arranged such that the photoelectric surface is located at a transfer position of the second transfer optical system;
a third transfer optical system configured to transfer the image of the target at the fluorescent surface;
an image sensor arranged at a transfer position of the third transfer optical system and configured to capture the image of the target transferred by the third transfer optical system; and
a moving mechanism capable of moving the mask by an amount equal to or larger than the opening.

20. An electronic device manufacturing method, comprising:
inspecting a defect of a reticle by irradiating the reticle with extreme ultraviolet light generated by an extreme ultraviolet light generation apparatus;
selecting a reticle using a result of the inspection; and
exposing and transferring a pattern formed on the selected reticle onto a photosensitive substrate,
the extreme ultraviolet light generation apparatus including:
a chamber in which a target supplied to a plasma generation region at inside thereof is turned into plasma and the extreme ultraviolet light is generated;
a target generator configured to supply the target to the plasma generation region in the chamber;
an illumination device connected to the chamber and configured to output illumination light toward the target supplied from the target generator; and
an imaging device connected to the chamber and configured to receive the illumination light and capture an image of the target, and
the imaging device including:
a first transfer optical system configured to transfer the image of the target;
a mask having an opening formed at a transfer position of the first transfer optical system;
a second transfer optical system configured to transfer the image of the target at the opening;
an image intensifier having a photoelectric surface and a fluorescent surface and arranged such that the photoelectric surface is located at a transfer position of the second transfer optical system;
a third transfer optical system configured to transfer the image of the target at the fluorescent surface;
an image sensor arranged at a transfer position of the third transfer optical system and configured to capture the image of the target transferred by the third transfer optical system; and
a moving mechanism capable of moving the mask by an amount equal to or larger than the opening.
